(19) United States
(12) Patent Application Publication
(10) Pub. No.: US 2026/0282578 A1
(43) Pub. Date: Sep. 17, 2026

(54) Aperture-Metasurface and Hybrid Refractive-Metasurface Imaging Systems

(71) Applicant: Metalenz, Inc., Boston, MA (US)

(72) Inventors: Robert C. Devlin, Concord, MA (US); John Graff, Swampscott, MA (US)

(73) Assignee: Metalenz, Inc., Boston, MA (US)

(21) Appl. No.: 19/664,802

(22) Filed: Apr. 30, 2026

Related U.S. Application Data
(63) Continuation of application No. 18/433,269, filed on Feb. 5, 2024, now Pat. No. 12,641,900.
Application No. 18/433,269 is a continuation of application No. 16/938,823, filed on Jul. 24, 2020, now Pat. No. 11,978,752.
(60) Provisional application No. 62/878,962, filed on Jul. 26, 2019.

(51) Int. Cl. H10F 39/00; G02B 1/00; G02B 5/18; G02B 27/09; G02B 27/42; H04N 23/55

(52) U.S. Cl. CPC H10F 39/806; G02B 1/002; G02B 5/1809; G02B 5/1814; G02B 27/0944; G02B 27/0988; G02B 27/4233; G02B 27/4244; G02B 27/4294; H04N 23/55; H10F 39/804; H10F 39/8053

(57) ABSTRACT

Hybrid imaging systems incorporating conventional optical elements and metasurface elements with light sources and/or detectors, and methods of the manufacture and operation of such optical arrangements are provided. Systems and methods describe the integration of apertures with metasurface elements and refractive optics with metasurface elements in illumination sources and sensors.

### CROSS-REFERENCE TO RELATED APPLICATIONS

The current application is a continuation of U.S. patent application Ser. No. 18/433,269, entitled “Aperture-Metasurface and Hybrid Refractive-Metasurface Imaging Systems”, filed Feb. 5, 2024 and published as US 2024-0234461 A1 on Jul. 11, 2024, which is a continuation of U.S. patent application Ser. No. 16/938,823, filed Jul. 24, 2020, which claims priority to U.S. Provisional Patent Application No. 62/878,962, filed Jul. 26, 2019, the disclosures of which are incorporated herein by reference in their entireties for all purposes.

### FIELD OF THE INVENTION

The current disclosure is directed to optical arrangements of metasurface elements, integrated systems incorporating refractive optics, light sources and/or detectors with such metasurface elements, and methods of the manufacture of such optical arrangements and integrated systems.

### BACKGROUND OF THE INVENTION

Metasurface elements are diffractive optics in which individual waveguide elements have subwavelength spacing and have a planar profile. Metasurface elements have recently been developed for application in the UV-IR bands (300-10,000 nm). Compared to traditional refractive optics, metasurface elements abruptly introduce phase shifts onto light field. This enables metasurface elements to have thicknesses on the order of the wavelength of light at which they are designed to operate, whereas traditional refractive surfaces have thicknesses that are 10-100 times (or more) larger than the wavelength of light at which they are designed to operate. Additionally, metasurface elements have no variation in thickness in the constituent elements and thus are able to shape light without any curvature, as is required for refractive optics. Compared to traditional diffractive optical elements (DOEs), for example binary diffractive optics, metasurface elements have the ability to impart a range of phase shifts on an incident light field, at a minimum the metasurface elements can have phase shifts between 0-2π with at least 5 distinct values from that range, whereas binary DOEs are only able to impart two distinct values of phase shift and are often limited to phase shifts of either 0 or 1π. Compared to multi-level DOE's, metasurface elements do not require height variation of its constituent elements along the optical axis, only the in-plane geometries of the metasurface element features vary.

### BRIEF SUMMARY OF THE INVENTION

The application is directed to optical arrangements of metasurface elements, integrated systems incorporating light sources and/or detectors with such metasurface elements, and methods of the manufacture of such optical arrangements and integrated systems.

Many embodiments are directed to imaging system including:
at least one image sensor;
a substrate layer having a substrate thickness disposed above the at least one image sensor by a first distance, the substrate layer configured to be transparent to a target wavelength of light, the substrate layer having a first surface distal the at least one image sensor and a second surface proximal the at least one image sensor;
an aperture disposed on the first surface of the substrate and having an aperture opening disposed therein; and
a single layer of a plurality of identical or unique nanostructured elements comprising a metasurface disposed on the second surface, such that light impinging on the aperture opening passes through at least a portion of the metasurface such that a specified angular deflection is imposed thereby;
wherein the distance between the aperture and the layer of metasurface elements are separated by a second distance determined by the substrate thickness; and
wherein the aperture and the layer of metasurface elements are configured to gather light of a specified operational bandwidth across a specified field of view and shift the incoming light such that it comes to a focus on the at least one image sensor at a zero or near-zero degree chief ray angle.

In still many embodiments, the system further includes a glass cover disposed atop the at least one image sensor.

In yet many the first distance is determined by a spacing layer comprised of one of either a solid-state spacer material or an air gap.

In still yet many embodiments, the field of view is at least ±30 degrees.

In yet still many embodiments, the system further includes a narrow bandwidth optical filter disposed between the metasurface elements and the at least one image sensor

Various embodiments are directed to an imaging system including:
at least one image sensor;
a substrate layer having a substrate thickness, the substrate layer configured to be transparent to a target wavelength of light, the substrate layer having a first surface distal the at least one image sensor and a second surface proximal with the at least one image sensor;
an aperture disposed above the substrate and having an aperture opening disposed therein; and
a single layer of a plurality of identical or unique nanostructured elements comprising a metasurface disposed on one of either the first or second surfaces, such that light impinging on the aperture opening passes through at least a portion of the metasurface such that a specified angular deflection is imposed thereby;
wherein the distance between the aperture and the metasurface layer are separated by a first distance; and
wherein the aperture and the metasurface layer are configured to gather light of a specified operational bandwidth across a specified field of view and shift the incoming light such that it focuses on the at least one image sensor at a zero or near-zero degree chief ray angle.

In still various embodiment, the system further includes an airgap between the second surface of the substrate and the image sensor.

In yet various embodiments, a spacer layer is disposed within the airgap.

In still yet various embodiments, the metasurface layer is disposed on the first surface.

In still yet various embodiments, the system further includes a narrow bandwidth optical filter disposed on the second surface between the metasurface elements and the at least one image sensor.

In yet still various embodiments, at least a portion of the aperture is interconnected with the first surface.

In still yet various embodiments, the metasurface layer is disposed on the second surface.

In yet still various embodiments, the image sensor is in contact with the second surface.

In still yet various embodiments, the field of view is at least ±30 degrees.

Several embodiments are directed to an imaging system including:
at least one image sensor;
substrate layer having a substrate thickness, the substrate layer configured to be transparent to a target wavelength of light, the substrate layer having a first surface distal the at least one image sensor and a second surface proximal with the at least one image sensor;
at least one refractive lens disposed above the substrate and configured to focus impinging light on the first surface of the substrate layer; and
a single layer of a plurality of identical or unique nanostructured elements comprising a metasurface disposed on one of either the first or second surfaces, such that light impinging on the at least one refractive lens passes through at least a portion of the metasurface elements such that an angular deflection is imposed thereby;
wherein the distance between the at least one refractive lens and the layer of metasurface elements are separated by a first distance; and
wherein the refractive lens and the layer of metasurface elements are configured to gather light of a specified operational bandwidth across a specified field of view and shift the incoming light such that it focuses on the at least one image sensor at a zero or near-zero degree chief ray angle.

In still several embodiments, the system further includes an airgap between the second surface of the substrate and the image sensor.

In yet several embodiments, a spacer layer is disposed within the airgap.

In still yet several embodiments, the metasurface layer is disposed on the first surface.

In yet still several embodiments, the system further includes a narrow bandwidth optical filter disposed on the second surface between the metasurface elements and the at least one image sensor.

In still yet several embodiments, at least a portion of at least one of the refractive lenses is interconnected with the first surface.

In yet still several embodiments, the metasurface layer is disposed on the second surface.

In still yet several embodiments, the image sensor is in contact with the second surface.

In yet still several embodiments, the field of view is at least ±30 degrees.

In still yet several embodiments, the at least one refractive lens is selected from the group consisting of plano-convex, convex-plano, bi-convex, bi-concave, plano-concave, or concave-plano.

In yet still several embodiments, the system includes at least two refractive lenses comprising a convex-concave lens and concave-convex lens.

In still yet several embodiments, the system includes at least three refractive lenses comprising a convex-concave lens, a bi-convex lens and a concave-plano lens.

In various of the above embodiments, at least the imaging sensor and metasurface have rectangular geometries.

In still various of the above embodiments, the at least one refractive lense proximal to the metasurface has a circular geometry.

In yet various of the above embodiments, the image sensor is characterized by a vertical, v, and a horizontal, h, dimension, and wherein the at least one refractive lens is characterized by the f-number of the lens, N, defined as N=f/D where f is the focal length of the optical system and D is the diameter of the lens, and wherein a metalense lens width is given by: =v+f/N, and wherein a metalense length l given by: l=h+f/N.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as exemplary embodiments of the invention and should not be construed as a complete recitation of the scope of the invention, wherein:

FIG. 1 provides a schematic illustrating an aperture-metasurface imaging system incorporating a cover glass above the image sensor in accordance with embodiments of the invention.

FIG. 2 provides a schematic illustrating a ray tracing diagram including the chief ray angle at the image sensor plane for the aperture-metasurface imaging system of FIG. 1 in accordance with embodiments of the invention.

FIG. 3 provides a schematic illustrating an aperture-metasurface imaging system with an air gap between the aperture and metasurface in accordance with embodiments of the invention.

FIG. 4 provides a schematic illustrating a ray tracing diagram including the chief ray angle at the image sensor plane for the aperture-metasurface imaging system of FIG. 3 in accordance with embodiments of the invention.

FIG. 5 provides a schematic illustrating an aperture-metasurface imaging system incorporating an air gap above the image sensor and the metasurface layer closer to the object plane in accordance with embodiments of the invention.

FIG. 6 provides a schematic illustrating an aperture-metasurface imaging system incorporating an air gap above the image sensor and the metasurface layer closer to the image plane in accordance with embodiments of the invention.

FIG. 7 provides a schematic illustrating an aperture-metasurface imaging system incorporating an air gap above the image sensor and spacers between the aperture and the metasurface in accordance with embodiments of the invention.

FIG. 8A provides a data graphs showing the relative illumination versus field of view for an aperture-metasurface imaging system in accordance with embodiments of the invention.

FIG. 8B provides a data graph showing the field of view versus degree of distortion for an aperture-metasurface imaging system in accordance with embodiments of the invention.

FIG. 8C provides data graphs showing a modulus transfer function over a field of view of 40 degrees for an aperture-metasurface imaging system in accordance with embodiments of the invention.

FIG. 8D provides an image of a standard test target taken using an aperture-metasurface imaging system in accordance with embodiments of the invention.

FIG. 9 provides a schematic illustrating a single refractive element and metasurface hybrid imaging system in accordance with embodiments of the invention.

FIGS. 10A and 10B provide schematics illustrating multiple refractive element and metasurface hybrid imaging systems in accordance with embodiments of the invention.

FIG. 11A provides a schematic of an image sensor wafer in accordance with embodiments of the invention.

FIG. 11B provides a schematic of an image sensor die in accordance with embodiments of the invention.

FIG. 12A provides a schematic of a spacer wafer in accordance with embodiments of the invention.

FIG. 12B provides a schematic of a spacer in accordance with embodiments of the invention.

FIG. 13 provides a schematic illustrating an integrated hybrid imaging system incorporating refractive elements with metasurface elements and spacers in accordance with embodiments of the invention.

FIG. 14 provides a schematic illustrating an integrated hybrid imaging system incorporating refractive elements with metasurface elements in accordance with embodiments of the invention.

FIG. 15 provides a schematic illustrating a fabrication process for a hybrid refractive element and metasurface imaging system in accordance with embodiments of the invention.

FIG. 16 provides a schematic illustrating an imaging system incorporating a rectangular metasurface lens element in accordance with embodiments of the invention.

FIGS. 17A and 17B provide schematics illustrating the relative dimensions of an imaging sense (FIG. 17A) and a rectangular metasurface lens element (FIG. 17B) in accordance with embodiments of the invention.

FIGS. 18A to 18D provide schematics illustrating optical systems of a N number of apertures over N number of rectangular lenses over a single image sensor in accordance with embodiments of the invention.

### DETAILED DESCRIPTION OF THE INVENTION

Turning now to the drawings, hybrid imaging systems incorporating conventional optical elements and metasurface elements with light sources and/or detectors, and methods of the manufacture and operation of such optical arrangements are provided. Many embodiments are directed to systems and methods for integrating apertures with metasurface elements in illumination sources and sensors. Various embodiments, are directed to systems and methods for integrating refractive optics with metasurface elements in illumination sources and sensors.

Embodiments of many optical imaging systems may incorporate a single aperture and single metasurface layer operable to correct for aberrations over a large field of view. Many embodiments of such single aperture and metasurface imaging systems are configured to be telecentric (e.g., having a near 0 degree angle of incidence at image sensor plane) over large field of view such that there is no fall-off in relative illumination over the field of view (e.g., that the intensity from on-axis rays is nearly identical to the intensity at the edge of the field-of-view).

In many embodiments, hybrid refractive optic and metasurface imaging systems may comprise metasurface elements that are free-standing (i.e., not directly integrated with a specific illuminator or sensor into a system). In some embodiments, the optical system may consist of a single physical component or substrate having a metasurface element disposed on either side thereof. In some embodiments, multiple refractive optics may be combined with at least one metasurface element to make more complex systems.

In embodiments of hybrid aperture or refractive optic and metasurface imaging systems the metasurface may be disposed on a surface of a supporting substrate either facing the aperture or facing the imaging system. In various embodiments airgaps may be disposed between the aperture and metasurface structure and/or between the metasurface substrate and the imaging system. Airgaps between elements may further comprise spacer structures to provide support therefor.

In many embodiment, the metasurface element may be free standing or may be embedded within another material. In various such embodiments, the selection of the embedding material includes the appropriate selection of refractive index and absorption characteristics. In many such embodiments, the embedding material may provide mechanical stability and protection as well as an additional design degree of freedom that enables the metasurface to perform a desired optical function.

In some embodiments, a spacing layer of a defined thickness (e.g., the working distance) may be deposited on the CMOS image sensor, LED, VCSEL, etc., to implement an optical distance appropriate for a desired camera design, illuminator design or optimal system performance. In various such embodiments, the spacing layer material may be organic or inorganic and may have a lower refractive index than the dielectric elements comprising the metasurface. In some such embodiments, the thickness of the spacing layer may be modified to provide appropriate optical spacing for the specific optical system.

Various embodiments are also directed to methods of fabricating hybrid metasurface imaging systems. In some such embodiments, methods are directed to the manufacture of metasurface elements on a wafer incorporating other devices, such as sensors or illuminators, thereby avoiding, in some embodiments, expensive manufacturing processes, such as, for example, the mechanical assembly of small dimension elements, or the active alignment of optics with sensors. In some such embodiments, metasurface elements may be integrated with the sensor (or the illuminator) in a series of operations at a semiconductor fab. In many such embodiments a sequence may include: (i) sensor or illuminator, (ii) optional microlens array/collimator, optional filter, optional spacing layer, optional metasurface element, optional additional spacing layer, optional refractive optic or aperture elements, optional anti-reflection (AR) layer, optional protection layer. In many such embodiments a sequence of elements may include: (i) sensor or illuminator, (ii) optional microlens array/collimator, optional filter, optional spacing layer, optional metasurface element, optional additional spacing layer, and optional refractive element or aperture.

### Embodiments for Implementing Aperture/Metasurface Imaging Systems

Typically to form an optical system that is corrected for aberrations over a selected field of view, the system must comprise multiple optical surface or multiple optical elements (e.g., two or more). This is true for both conventional refractive optical systems and metasurface optical systems. Specifically, only optical systems with two or more metasurfaces and sufficiently low aberrations over some field of view have been demonstrated. Various embodiments are directed to imaging systems that integrate an aperture and a single metasurface element, that allow for the combined system to achieve high quality imaging over a large field of view, telecentricity (e.g., near 0 degree of incidence at the image sensor plane) over a large field of view, and with no fall-off in relative illumination.

Specifically, such systems may be used in imaging systems such as CMOS cameras, (such as those used in cell phones, computers, tablets etc., for collecting images of a scene of visible light or in the infrared for biometric authentication). These CMOS imaging systems require an increased field-of-view (FOV), independent control of the chief ray angle (CRA) as a function of field height at the CMOS image sensor, and minimal optical distortion of the scene being imaged. These terms will be understood to have a meaning conventional to those skilled in the art. For traditional imaging systems, comprised of refractive lenses, as many as five or six unique lenses must be combined to perform this function. Similarly, in conventional metasurface imaging systems implement multiple metasurface elements to provide enough degrees of freedom to adequately control these parameters (CRA, FOV and minimizing distortion). However, various embodiments show that by combining an aperture with a single metasurface, an imaging system with a wide FOV, controllable distortion and controllable CRA can be realized in accordance with embodiments.

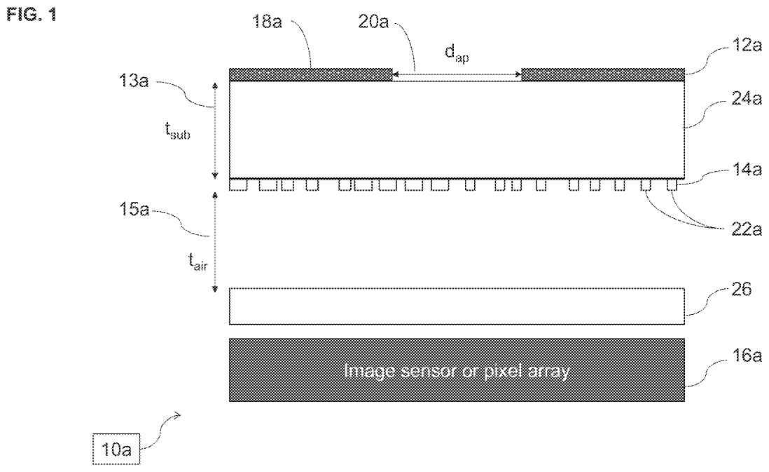

An exemplary embodiment of such a system is illustrated in FIGS. 1 to 7. As shown, in many such embodiments the system (10a to 10d) generally comprises an aperture structure (12a to 12d) disposed a set distance (13a to 13d) away from a metasurface layer (14a to 14d), which itself is set a distance (15a to 15d) away from an image sensor (16a to 16d). As will be described in greater detail below, in such systems it will be understood that the distance between the aperture and metasurface layer, and the distance between the metasurface layer and the imaging system (e.g., the back focal length of the imaging system) may take the form of an air gap or an optically transmissive material (e.g., substrate etc.).

For the purposes of many embodiments, the aperture structure (12a to 12d) comprises a first aperture structure portion (18a to 18d) which is opaque to light at the wavelength of interest and a second aperture structure portion (20a to 20d) that is completely transparent to light at the wavelength of interest over a distance (dₐₚ). In various embodiments such aperture structures impart no optical function (e.g., does not deflect light rays) but rather limits the lateral extent of a light ray bundle entering the imaging system, or otherwise equivalently sets the entrance aperture of the imaging system.

For purposes of many embodiments, the metasurface layer (14a to 14e) generally comprises a plurality of nanostructures (22a to 22e) disposed on a substrate (24a to 24e) defined by a substrate thickness (t_{sub}) which may be formed of any material transparent at the wavelength of interest. In many embodiments of hybrid aperture/metasurface imaging systems, the metasurface layer is the only functional layer provided that significantly deflects incident light rays to form a focused image (e.g., the metasurface layer operates as an arbitrary phase mask.

Embodiments of nanostructures generally comprise identical or unique three dimension elements (e.g., square, round, triangular, oval, etc.) having feature sizes smaller than the wavelength of light within the specified operational bandwidth and configured to impose a phase shift on impinging light within the plane of plurality separated by macroscopic distances (distances of 10 or more wavelengths), such that in combination the metasurface layer performs a single optical function. Each individual metasurface in the optical system, may be configured to have some specific 2D phase and transmission function, φ(x,y) and t(x,y), that it carries out. While in general each metasurface may have a unique distribution of phase and transmission, the nanostructure elements that comprise any metasurface embedded in the same material, with the same base composition and at a specific wavelength are identical. In most practical single wavelength applications, the transmission can be configured to be maximized (near 1) and uniform across the metasurface while the phase can be configured to take on values between 0 and 2π. In summary, according to embodiments, for some wavelength of interest, material system (metasurface material and embedding material), fixed thickness and element spacing, a set of in-plane dimensions of the comprising nanostructures may be configured such that phase delays from 0 to 2π can be imprinted on an incident light field. Thus for different implementations of metasurface designs at the fixed material and wavelength conditions, the only variable from design to design is the distribution of suitable nanostructure elements across the metasurface.

Metasurface layers according to some embodiments may be designed to be freestanding, i.e., the metasurface elements protrude from the end of the substrate with only air gaps separating them, the process is complete at this step. In other embodiments metasurfaces may be further configured to have an AR coating or mechanical protection. In some such embodiments, in order to protect the metasurface and provide improved functionality, the metasurface constituent elements and substrate faces may be coated in some material or layers of material. In embodiments with embedded metasurface elements, the elements, which can be any material with desired optical properties, are embedded in a lower-index of refraction medium. The low-index medium completely encapsulates the metasurfaces and extends some thickness above the metasurface elements. The low-index medium acts as a protective barrier to the metasurface elements (i.e., provide mechanical stability) and provides an additional design degree of freedom for the system that allows for certain properties to be optimized, e.g., overall transmission or efficiency of the metasurface.

Metasurface layers or metasurface systems according to embodiments can be fabricated in mass production using any suitable fabrication techniques, including, for example, lithography, machining, etching, and standard CMOS fabrication techniques, as has been previously described in U.S. patent application Ser. No. 16/120,174, filed Aug. 31, 2018, the disclosure of which is incorporated herein by reference. The metasurface substrate may be any low-index material, e.g., polymer, SiO₂, glass. The metasurface elements may also be any material which has been optimized for a specific bandwidth, e.g., silicon, TiO2, alumina, metal, etc.

The imaging system may take the form of a single monolithic image sensor or a pixel array. Such image sensors and pixel arrays may take any suitable form including, for example, CMOS sensors.

FIG. 1 provides a schematic illustration of an implementation of various embodiments of such hybrid aperture/metasurface imaging systems. As shown, in many embodiments a substrate layer (24a) transparent at the wavelength of interest and having a thickness (t_{sub}) is provided having an aperture structure (12a) which is opaque to light at the wavelength of interest and completely transparent to light at that wavelength of interest over a distance, (dₐₚ) disposed on a first side distal to the imager (16a), and a metasurface layer (14a) composed of nanostructures (22a) with equal height disposed on a second side proximal to the imager (16a). In such embodiments the aperture structure (12a) and metasurface layer (14a) are separated by a first distance (13a) defined by the substrate thickness (t_{sub}). Further in such embodiments, the aperture structure (12a) and metasurface layers (14a) may be deposited directly on the substrate (24a) or bonded via adhesive. Between the metasurface layer (14a) and the imager (16a) is disposed a distance (15a) defining the back-focal length formed by an air gap (tₐᵢᵣ). Although not required, many embodiments of such imaging systems may further comprise an optional cover glass or filter (26) which does not impact the imaging performance of the device but provides other functionality (e.g., either optical or structural).

It will be understood that in such embodiments, the aperture imparts no optical function (does not deflect the light rays) but rather only limits the lateral extent of the light ray bundle that may enter the imaging system, or equivalently sets the entrance aperture or the f/# of the system. Meanwhile, the metasurface layer may comprise the only functional optical layer that significantly deflects the light rays to form a focused image in such embodiments. In some such embodiments, the metasurface layer may act as an arbitrary phase mask, imparting any value from 0 to 2π phase shift on the incident light at an arbitrary radial position of the lens.

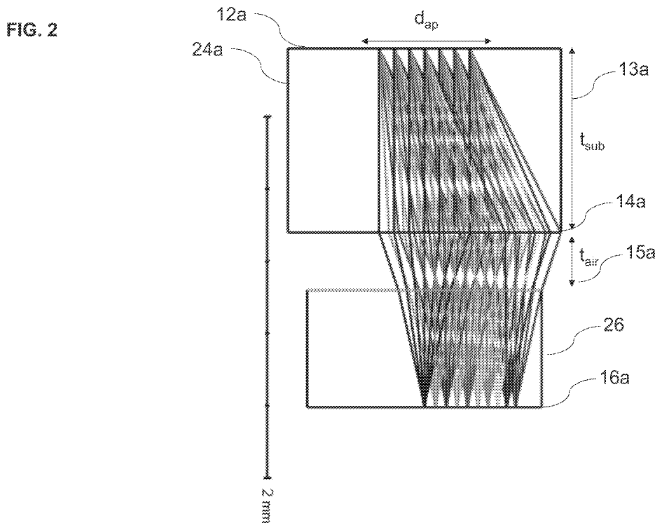

Referring to FIG. 2, a ray-tracing diagram through an exemplary embodiment of a system comprising a single aperture (12a) and a single metasurface (14a) combined on a single substrate (24a) in accordance with the embodiment illustrated in FIG. 1 is provided. (Although not described in detail here, it will be understood that these metasurface elements could be fabricated using methods as described herein or in previously cited U.S. patent application Ser. No. 16/120,174 using a suitable conformal deposition process, such as, for example, low pressure chemical vapor deposition or atomic layer deposition.) In this exemplary embodiment, the aperture and metasurface elements have been configured such that in combination they are able to form a good image across a wide FOV (±40 degrees in this example, however, it will be understood that this is not a limiting case). Embodiments of such a single aperture and single metasurface system, as shown, have been surprisingly found to naturally produce focused rays at the image plane that are telecentric (i.e., having 0 degree CRA). In short, while traditional refractive and metasurface designs require complex, many-element systems to realize such telecentric designs, in accordance with embodiments only a single aperture and single metasurface element are needed to achieve similar telecentricity. This telecentricity in turn leads to improved optical properties. In particular, the low (e.g., zero or near zero degree CRA) allows for a narrowing of the bandwidth of the optical filter (26) for narrowband applications. In traditional refractive designs, especially for compact mobile applications, CRAs in are typically on the order of 15 degrees to 30 degrees. These larger CRAs in turn require the filter bandwidth to be significantly increased allowing for more ambient light to enter the detector. In narrowband applications (e.g., a near IR VCSEL array), such ambient light can be a persistent noise source. Thus, embodiments of a combined metasurface/filter system such as that shown in FIG. 2 allow for better ambient light performances.

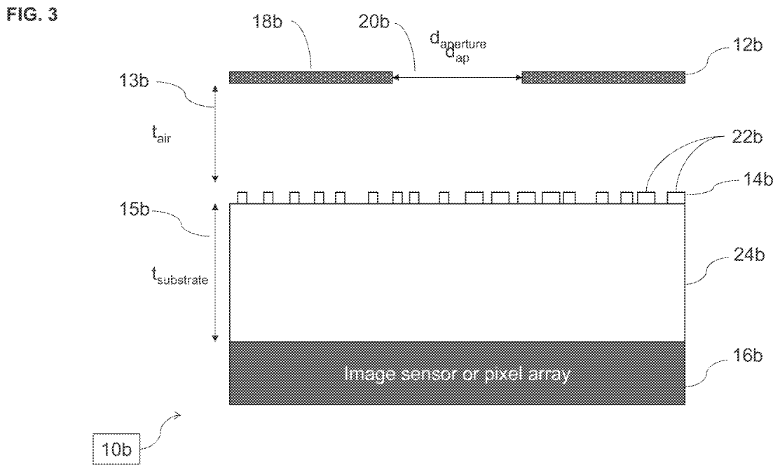

Although FIGS. 1 and 2 provide one arrangement of optical elements for a hybrid aperture/metasurface imaging system, it will be understood that many other arrangements of elements may be realized. For example, FIG. 3 provides a schematic illustration of embodiments of imaging systems in which the position of the airgap and substrate have been exchanged. Such a structure allows for the formation of a thinner imaging system, but entails a more complicated assembly process. In particular, as shown in FIG. 3, such imaging system embodiments comprise a substrate (24b) transparent at the wavelength of interest and having a thickness (t_{sub}) provided having a metasurface layer (14b) composed of nanostructures (22b) with equal height disposed on a first side distal to the imager (16b), and on a second side the imager (16b). In such embodiments, the metasurface layers (14b) and the imager (16b) may be directly bonded via adhesive or other suitable means. Between the metasurface layer (14b) and the imager (16b) is disposed a distance (15b) defining the back-focal length formed by the substrate thickness (t_{sub}). This distance is used as a free parameter to design imaging systems with optimal performance and will change based on the desired f/# or field of view of the imaging system, for example. In such embodiments such imaging systems do not require the optional cover glass or filter used in the embodiment shown in FIG. 1 as the substrate (24b) provides such dual functionality. In such embodiments the aperture structure (12b), which is opaque to light at the wavelength of interest and completely transparent to light at that wavelength of interest over a distance, (dₐₚ), and metasurface layer (14b) are separated by a first distance (13b) defined by and airgap (tₐᵢᵣ).

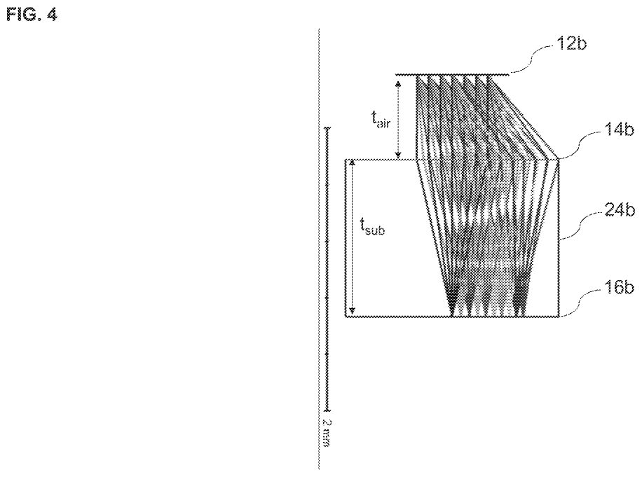

Referring to FIG. 4, a ray-tracing diagram through an exemplary embodiment of a system comprising a single aperture (12b), along with a single metasurface (14b) and an imager (16b) combined on a single substrate (24b) in accordance with the embodiment illustrated in FIG. 3 is provided. (Although not described in detail here, it will be understood that these metasurface elements could be fabricated using methods as described herein or in previously cited U.S. patent application Ser. No. 16/120,174 using a suitable conformal deposition process, such as, for example, low pressure chemical vapor deposition or atomic layer deposition.) In this exemplary embodiment, the aperture and metasurface elements have been configured such that in combination they are able to form a good image across a wide FOV (±40 degrees in this example, however, it will be understood that this is not a limiting case). Embodiments of such a single aperture and single metasurface system, as shown, have been surprisingly found to naturally produce focused rays at the image plane that are telecentric (i.e., having 0 degree CRA).

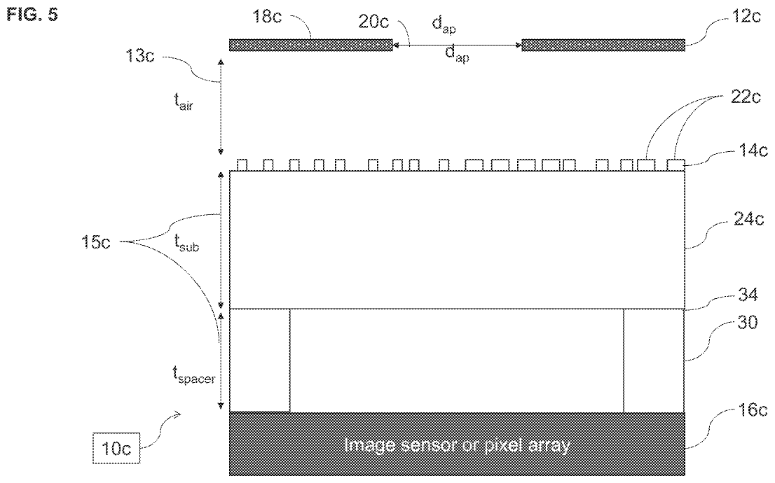

Although FIGS. 1 and 4 provide arrangements of optical elements for a hybrid aperture/metasurface imaging system in which an element is in direct contact with the image sensor, it will be understood that many other arrangements of elements incorporating spacers disposed between the image sensor and the substrate supporting the metasurface layer may be realized. For example, FIG. 5 provides a schematic illustration of embodiments of imaging systems in which a second airgap (28) is disposed within the imaging system.

In particular, as shown in FIG. 5, such imaging system embodiments comprise a substrate (24c) transparent at the wavelength of interest and having a thickness (t_{sub}) provided having a metasurface layer (14c) composed of nanostructures (22c) with equal height disposed on a first side distal to the imager (16c), and a second airgap (28) disposed between a second side of the metasurface layer proximal to the imager (16c). One advantage of such embodiments incorporating an air gap is that the light rays proceed through the system at higher angle, as compared to the embodiment shown in FIG. 1, for example, thus allowing for a decrease in the overall form factor of the metasurface optical system. In addition, the gap between the metasurface substrate and image sensor alloys for the introduction of other optical elements, including, for example, microlens arrays or optical color filters to improve optical function of the imaging system.

In such embodiments, the metasurface layers (14c) and the imager (16c) may be deposited directly on the substrate (24c) or bonded via adhesive. Such embodiments may also comprise suitable spacers (30) to support the substrate (24c) and maintain the distance between the substrate and the image sensor (16c). Between the metasurface layer (14c) and the imager (16c) is disposed a distance (15c) defining the back-focal length formed by the combination of the substrate thickness (t_{sub}) and a spacer height (t_{spacer}). The spacers (30) can be either fixed to the image sensor (16c) and substrate layer (24c), leading to a fixed distance for (t_{spacer}) or the substrate can be placed into a standard optical barrel and (t_{spacer}) can be adjustable post assembly. Such embodiments allow for the surface (34) of the substrate (24c) proximal to the image sensor (16c) to remain unpatterned, allowing for the direct integration of an optional optical filter thereon.

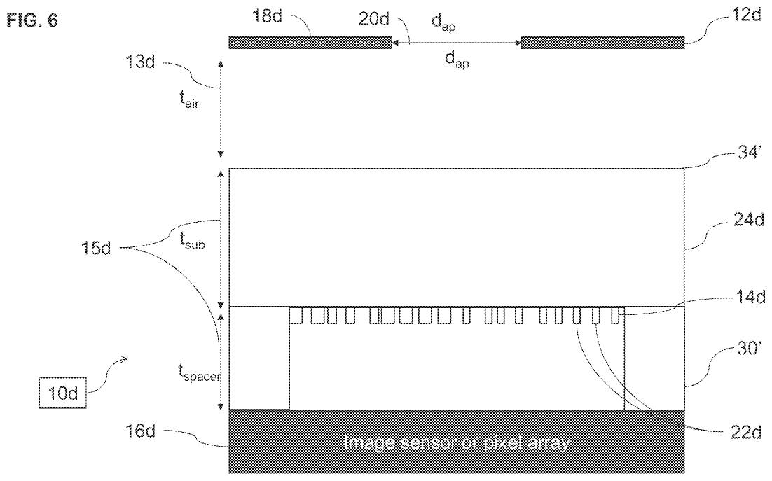

Although one embodiment of a configuration of a hybrid aperture/metasurface incorporating an airgap above the image sensor has been described, as shown in FIG. 6, in various embodiments the metasurface layer (14d) may also be disposed on the surface of the substrate (24d) proximal to the image sensor (16d) facing the air gap (32) supported by spacers (30′). Such an implementation allows for the protection of the metasurface elements from environmental contamination. Additionally, such embodiments allow for the surface (34′) of the metasurface substrate (24d) distal to the image sensor (16d) to remain unpatterned, allowing for the direct integration of an optional optical filter on the substrate. Again, in such embodiments the spacer (30′) can be either fixed to the image sensor (16d) and substrate (24d), leading to a fixed distance for (t_{spacer}) or the substrate (24d) can be placed into a standard optical barrel and (t_{spacer}) can be adjustable post assembly.

Accordingly, embodiments illustrated in FIGS. 5 and 6 illustrate that the metasurface elements may be arranged to face inward or outward with respect to the air gap between the substrate and image sensor. Production of the metasurface system illustrated in FIGS. 5 and 6 can follow processes described, for example, in U.S. patent application Ser. No. 16/120,174. The spacer layers may be any low-index material, e.g., polymer, SiO₂, glass.

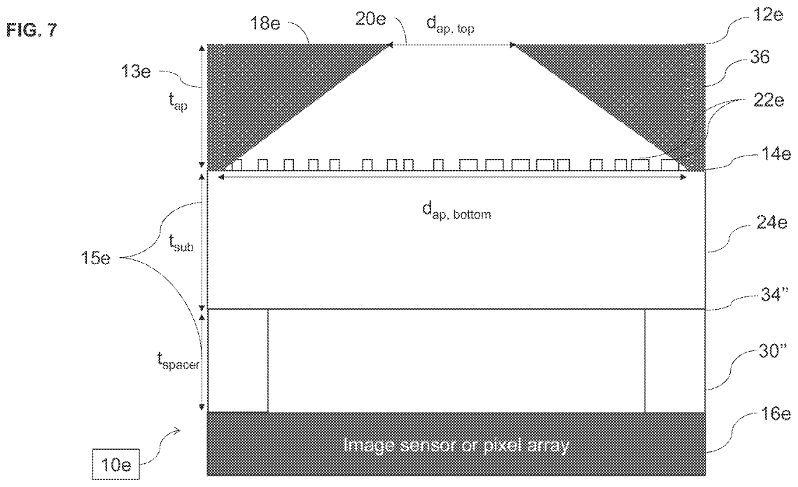

Although embodiments of hybrid aperture/metasurface imaging systems incorporating an airgap between the aperture and metasurface substrate have been shown in FIGS. 3, 5 and 6, these embodiments would require a separate supporting structure to secure the aperture and ensure the aperture distance (tₐᵢᵣ) remains constant. However, the aperture structure (12e) may also be attached directly to the substrate layer (24e). An exemplary embodiment of such an imaging system is illustrated in FIG. 7. As shown, in this exemplary embodiment the top aperture (12e) has an aperture body (36) with width d_{ap,top} that sets the entrance aperture of the system, has an aperture offset from the substrate by a distance (tₐₚ), and that is angled with a minimum angle set by the half field of view of the imaging system to a width of the aperture after a distance along the optical axis set by (tₐₚ) is set by the width of the metasurface layer and is given by (d_{ap,bottom}). Although the embodiment shown in FIG. 7 depicts a system in which the metasurface layer (14e) is disposed on a surface of the substrate (24e) distal from the image sensor (16e), it will be understood that the metasurface layer may also be disposed on the surface (34″) of the substrate proximal to the image sensor. In addition, it will be understood that while the exemplary embodiment incorporates a spacer structure (30″) and airgap between the substrate (24e) and image sensor (16e), embodiments may omit this element and mount the substrate directly atop the image sensor.

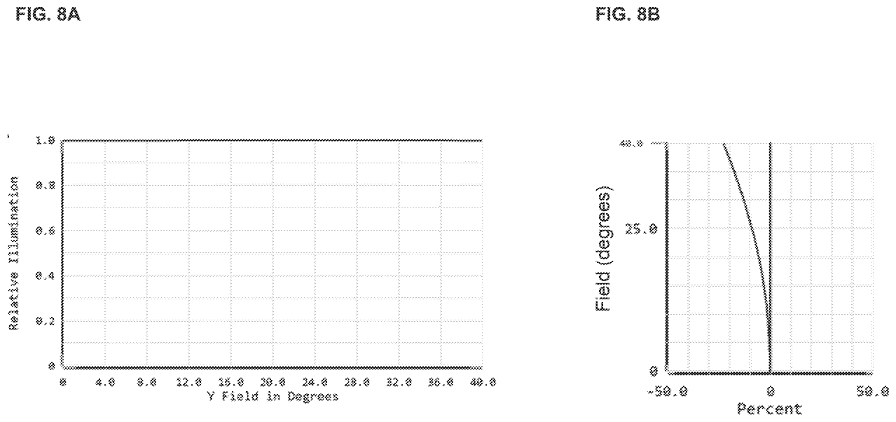

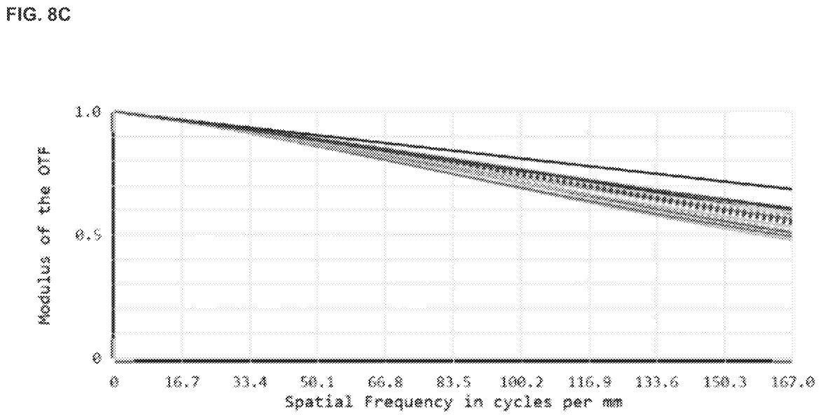

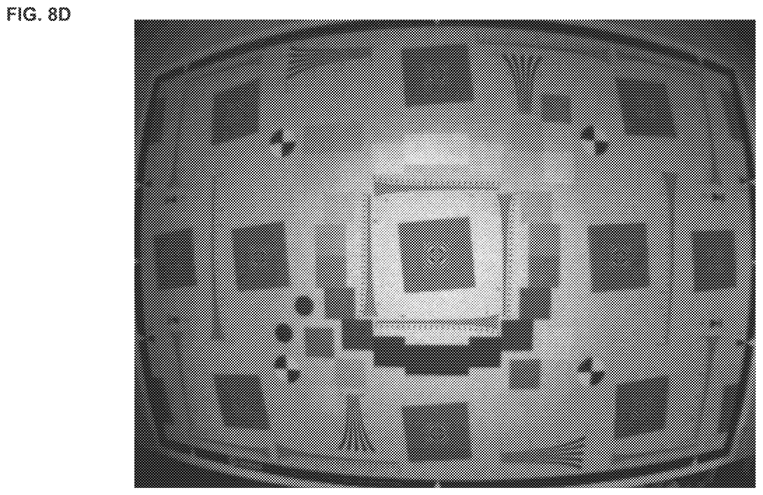

An attribute of embodiments of such telecentric designs is that the metasurface imaging system provides a more uniform illumination at the image sensor (referred to by those in the art as “relative illumination”). A data plot of relative illumination for an exemplary system according to embodiments is provided in FIG. 8A, and demonstrates that relative illumination for the aperture/metasurface imaging system is maintained at 100% across the entire field of view, which is a substantial improvement over conventional systems, which can have a difference between center and edge of 50% or more. Accordingly, embodiments of imaging systems are able to collect more total illumination across the full field of view. Embodiments of the metasurface system also provide an additional design variation with respect to traditional refractive lens systems. Typical CMOS image sensors (CIS) require a microlens to be associated with each pixel. Because there is a large variation in CRA across a given sensor plane that is inherent to refractive optical systems, the microlens array on the CIS also requires a complex CRA specification. However, in embodiments of metasurface systems as described herein, the CRA of the microlens array may be configured to be a constant 0 degrees across the CIS allowing for greater simplicity in the design and fabrication of the microlens array. Alternatively, in certain implementations the microlens array may be completely removed from the CIS, saving a process step in CIS production. Furthermore, such aperture metasurface systems with 0 CRA allow one to limit a persistent problem in traditional imaging systems known by those in the art as “pixel crosstalk”. Traditional refractive systems that send light into the image sensor are prone to light coupling into neighboring pixels, which adds noise to the system.

Conventional metasurface systems may be configured with multiple metasurface layers to control for FOV and distortion. The introduction of the additional metasurface element or elements, allow for the realization of a separate arbitrary phase profile, provides more degrees of freedom to control the path of the light rays as compared to a typical system comprised of an equivalent number refractive elements. In embodiments of the current imaging system where a single metasurface layer is used it is not possible to control CRA and correct for grid distortion simultaneously. As a result, a certain amount of grid distortion is inevitable. For example, FIG. 8B provides a data plot illustrating distortion as a function of field at the CMOS image sensor for an imaging system based on the embodiment shown in FIG. 1. FIG. 8C shows a plot of the modulus transfer function over the field of view for an embodiment of an imaging system as shown in FIG. 1. FIG. 8D provides a standard test image illustrating the grid distortion for an imaging system based on the embodiment shown in FIGS. 8A to 8C. As shown, at the edge of the field of view the quality drops off. However, embodiments of the invention show that all of the wavelengths of light are tightly bundled indicating that the distortion can be corrected simply using known image processing software.

### Embodiments Implementing Hybrid Refractive and Metasurface Elements

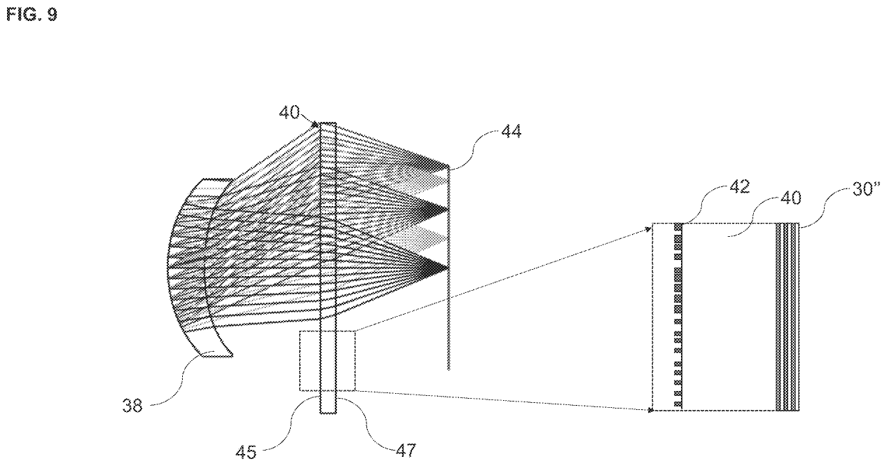

Although embodiments incorporating apertures and single metasurface layers have been described, it will be understood that embodiments are also directed to hybrid systems of metasurface elements incorporating refractive lens elements. FIG. 9 provides a schematic illustration of an implementation of various embodiments of such hybrid refractive lens/metasurface imaging systems. In many embodiments the hybrid imaging surface consists of at least one of each of the following: a refractive lens with one or more surface of curvature and a metasurface layer on a substrate where all of the elements comprising the metasurface are the same height. More generally, the hybrid optical system may be comprised of any number of refractive elements and multiple metasurface layers. In certain embodiments having the metasurface element on the substrate layer that is the final component prior to the image sensor provides the specific advantage of creating a so-called image-space telecentric imaging system. In addition, the substrate upon which the metasurface layer is formed may have a set of filter layers deposited. As described in embodiments incorporating a filter, the metasurface layer is closer to the object plane of the imaging system while the near infrared filter is closer to the image sensor.

An exemplary embodiment of a hybrid refractive element/metasurface imaging system is illustrated in FIG. 9. In many embodiments the system includes at least one refractive optic (38) disposed a set distance away from a substrate layer (40) transparent at the wavelength of interest and having a thickness (t_{sub}) having a metasurface layer (42) composed of nanostructures (44) with equal height disposed on a first surface (45) thereof that is distal to the image sensor (46), and an optional optical filter (48) disposed on a second side (47) of the substrate proximal to the imager.

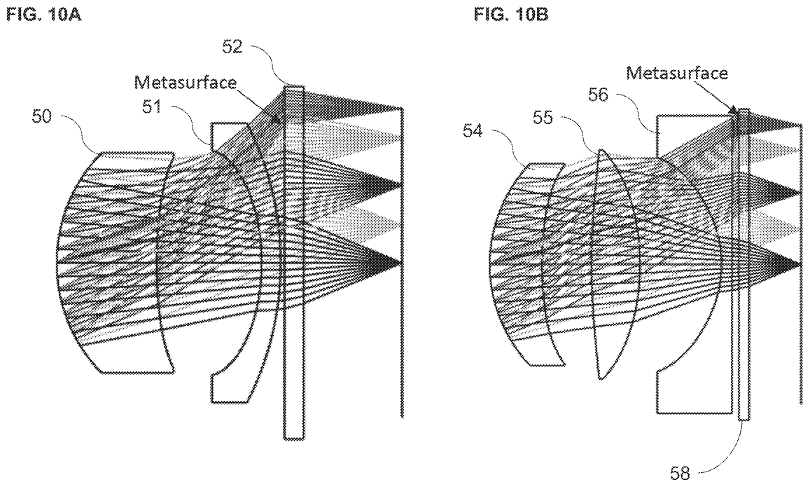

Although the embodiment shown in FIG. 9 illustrates a hybrid system having a single refractive optic and a single metasurface layer, it will be understood that embodiments may also incorporate other arrangements of refractive optics. Figures illustrating such metasurface/refractive hybrid systems are provided in FIGS. 10A and 10B. Specifically, FIG. 10A illustrates a hybrid system comprising two refractive elements (50 & 51) and one metasurface layer (52) system where the two refractive elements are convex-concave and concave-convex. FIG. 10B illustrates a hybrid system comprising three refractive elements (54, 55, 56) and one metasurface element (58) where the three refractive elements are convex-concave, bi-convex and concave-plano, respectively.

With regard to the refractive optical elements in the hybrid systems described above, i.e., those elements preceding the metasurface layer, it will be understood that the surface curvature of these elements may take on any positive, negative or infinite values. Accordingly, although specific arrangements of refractive elements are shown in the figures, the refractive elements may take any suitable form and combination for the specific application, including for example, plano-convex, convex-plano, bi-convex, bi-concave, plano-concave, or concave-plano.

### Embodiments Implementing Image Sensor Wafers

Imaging systems known in the art typically consist exclusively of traditional refractive lenses (glass or plastic materials with at least one curved surface). According to embodiments a single metasurface layer is disposed in combination with one or more, curved refractive lens. Surprisingly, it has been found that the inclusion of the single metasurface layer turns the optical system telecentric. Specifically, in many such embodiments, the inclusion of the metasurface element as the final element before the image plane makes the system telecentric.

Embodiments of metasurface layers may be integrated with the CMOS image sensor (CIS) as the cover glass and filter while the refractive optics can be assembled in barrels as is done conventionally in optical imaging modules. In certain embodiments the glass upon which the metasurface layer is fabricated, in addition to be a cover glass for the CIS, can have been previously deposited with dielectric layers and act as a near infrared bandpass or long pass filter. Such embodiments provide a single component with function in the optical imaging process as well as to eliminate unwanted wavelengths from being incident on the image sensor.

While the above embodiments have focused on hybrid metasurface imaging systems with a single sensor element, e.g., as shown in FIGS. 1 to 10B, metasurface elements can also be integrated with an image sensor wafer containing a plurality of image sensor dies. A figure illustrating a schematic for an image sensor wafer is shown in FIG. 11A. As shown, embodiments may comprise an image sensor wafer (60) comprising a set of image sensor dies (62), while this is shown in a periodically spaced 2D array, it will be understood that the array need not be periodically spaced. As shown in FIG. 11B, in turn, each sensor die (62) comprises an image sensor active area (64). Although each image sensor may be identical, in many embodiments the character of each sensor may be generally unique. Because each imager comprising array may have unique properties, it may also be advantageous to have an array of metasurface elements, each with uniquely designed properties.

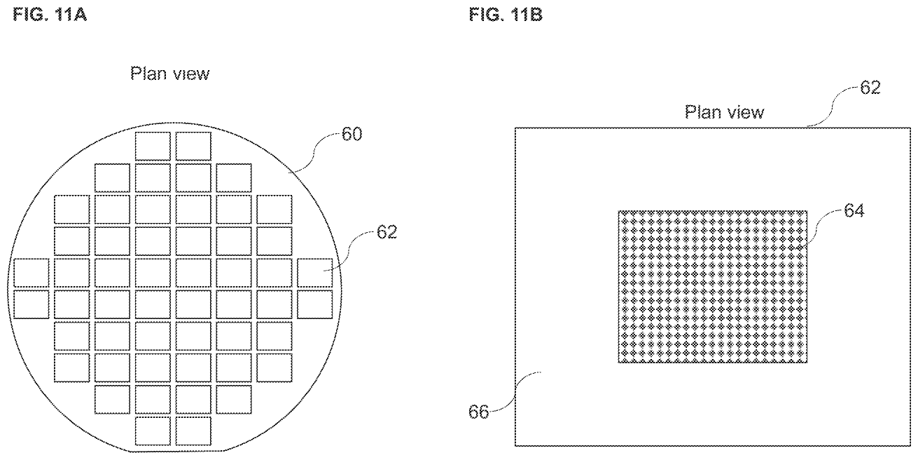

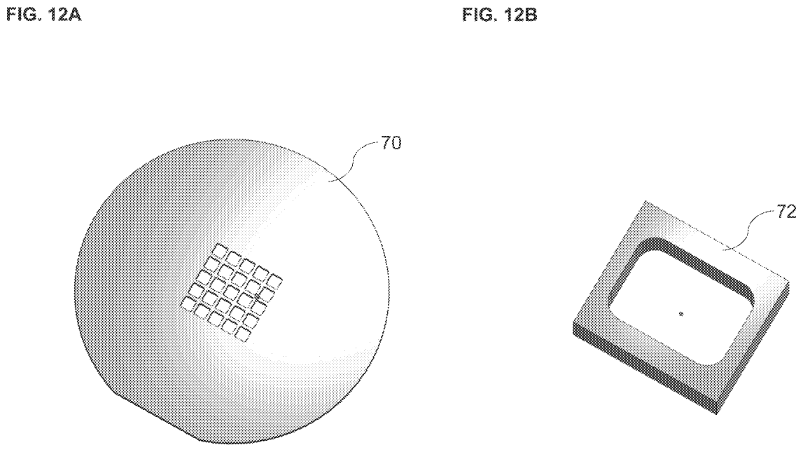

It will be understood that only the active area (64) need be available for imaging. The region outside of the image sensor active area (66) may be used to attach lenses or spacers. Moreover, in various embodiments the metasurface substrate may be offset from the image array by a spacer. Exemplary embodiments of a spacer wafer (70) comprising a plurality of spacer openings suitable for attachment to a sensor wafer, and a spacer die (72) suitable for attachment to an image sensor or lens die are illustrated in FIGS. 12A and 12B, respectively. The design and thickness of the spacer layer will depend on the specific configuration, but in many embodiments the thickness is configured to allow the light from the illumination sources to diverge sufficiently before interacting with image sensor. Again, the function of each metasurface element in the array may be generally unique, and may be patterned on top of each individual image sensor in the array, utilizing any suitable technique outlined for example in U.S. patent application Ser. No. 16/120,174. For example, a metasurface may be fabricated directly on each individual image sensor in the array or a suitable dielectric spacer may be deposited on the image sensor followed by the integration of the metasurface on top of the combined dielectric layer and image sensor. In such embodiments, the metasurfaces may provide a particular radiation pattern for each image sensor and the entire system (image sensor properties, geometrical parameters and metasurface-enabled radiation pattern) can be iteratively optimized for a specific set of performance parameters.

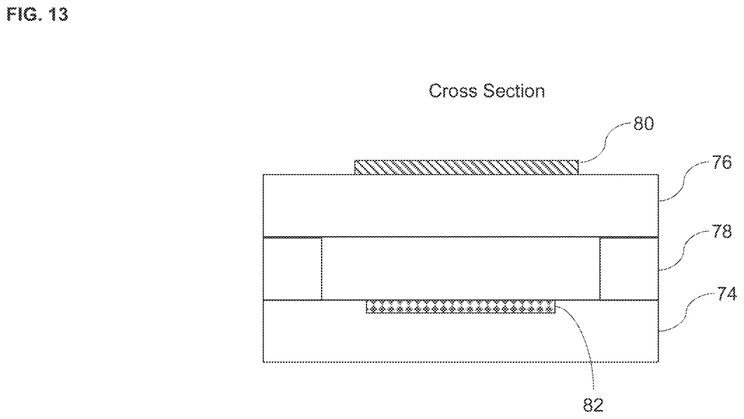

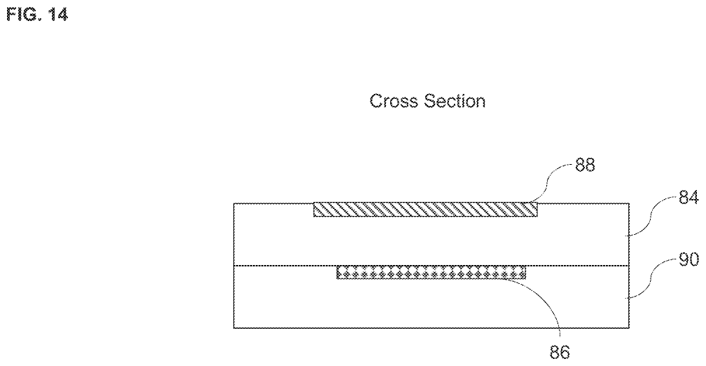

In various other embodiments, a dielectric material, with an index of refraction lower than that of the constituent image sensor material may be deposited and planarized such that a single metasurface can be patterned on top of the dielectric material. This contrasts with embodiments where each image sensor in the array has a unique metasurface patterned on its facet. Again, in such embodiments the combined system may be optimized to achieve a desired performance. Finally, in all of the above embodiments, integration of a metasurface with an image sensor array may be accomplished using wafer level optics processes. In such embodiments, the spacer layer may be air rather than a solid dielectric, illustrations of exemplary embodiments of such devices are shown in FIGS. 13 and 14.

Specifically, FIG. 13 shows a schematic of an embodiment comprising an image sensor die (74) and a lens die (76) separated by a spacer (78). In such embodiments, the spacer (78) controls the distance between the metasurface area (80) and the image sensor active area (82). The spacer in such embodiments can be attached to the image sensor die or image sensor wafer then the lens can be attached to the spacer. Alternatively the spacer can be first attached to the lens, then the sensor attached to the spacer. In such embodiments, the spacer can be attached using adhesives (e.g. UV-cured epoxy or thermal cured epoxy), solders, or fusion bond.

FIG. 14, illustrates and exemplary embodiment that excludes a spacer. In such embodiments, the thickness of the lens die (84) determines the distance between the image sensor active area (86) and the metasurface area (88). The image sensor die (90) and lens die (84) can be directly attached, using adhesive, solder, fusion bond, bump bond, etc. Alternatively the image sensor wafer and lens wafer can be attached directly at the wafer level as previously described.

As shown in FIG. 15, in certain embodiments, the refractive lenses (91) of hybrid systems may first be assembled in a lens barrel (92), as is already known in the art. The metasurface element (94) can then be combined with the CMOS image sensor element (96) as described above with respect to FIGS. 13 and 14, above. These two sub components are then assembled together to form the final system. In such embodiments, the refractive lenses may be configured to thread into a housing (98) such that the distance between the refractive elements and metasurface (t_{gap}) may be adjusted.

### Embodiments Implementing

As is well known in the arts, the image of a scene formed by a circular, radially-symmetric lens or system of circular, radially symmetric lenses will also be a circle. As a result, the geometry of the formed image is often referred to as the image circle of the lens. In modern photography, however, the medium recording the image (CMOS image sensor, e.g.) often has a rectangular shape. In the camera design, the image circle of the lens is designed such that the diameter of the image circle, D_{image}, is at least as large as the diagonal of the image sensor, d. However, since the image sensor is rectangular, only a portion of the image circle falls actually falls onto the image sensor. Thus, much of the lens area where light from a scene is incident is not used in the final formation of an image from the camera system.

In a traditional injection molded plastic refractive lens, the shape of the lens is kept ideally circular. The circular shape is used because from a manufacturing perspective circular shapes and radially-symmetric lenses are the easiest to achieve and most repeatable in production. Furthermore, there is minimal cost increase of making a circular lens with larger area rather than a rectangular lens with a smaller area. Thus, conventional cameras use circular lenses and only a portion of the light impinging upon the full circular lens is collected by the rectangular image sensor. These portions of the circular lens where light is incident but does not contribute to light falling on the image sensor are not used in the final image formation.

For the metasurface lenses according to various embodiments, the shape of the lens can be engineered such that the image it forms is uniquely matched with a specific image sensor dimension. In contrast to conventional refractive lenses, in many such embodiments, the lens shape is configured to be no longer circular and the lens to no longer form an image circle. In various embodiments the metasurface lens is formed in a rectangular configuration with specific dimensions and thus the formed scene image is also rectangular. In the ideal case of such a design embodiment, all of the light impinging on the rectangular metasurface lens falls onto the image sensor. Embodiments of metasurfaces having rectangular lenses break the radial symmetry and therefore the image that the lens forms is no longer circular or radially symmetric.

Accordingly, in many embodiments of lens systems the metasurface lens element may be formed in a rectangular configuration. Advantages of such rectangular or not circular lenses include: limiting the total area of the lens, eliminating portions of the lens that would otherwise have light impinge upon it that does not subsequently form an image on the image sensor, and simplifying post processing of lens wafers. Particular embodiments of rectangular metasurface lenses and the imaging systems are described here.

Many embodiments of metasurface lens systems having non-circular configurations have the following commonalities: an entrance aperture which is the stop of the lens system and a metasurface lens which is the final, active optical surface before the image sensor plane. In such embodiments, the entrance aperture (and optical stop) can be circular in cross-section, as it would be in a traditional optical system, while the metasurface lens can be patterned as a rectangle or other arbitrary shape.

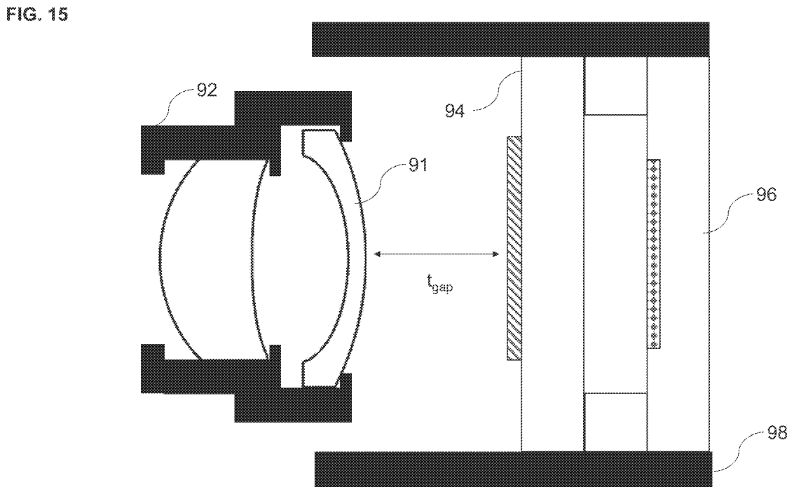

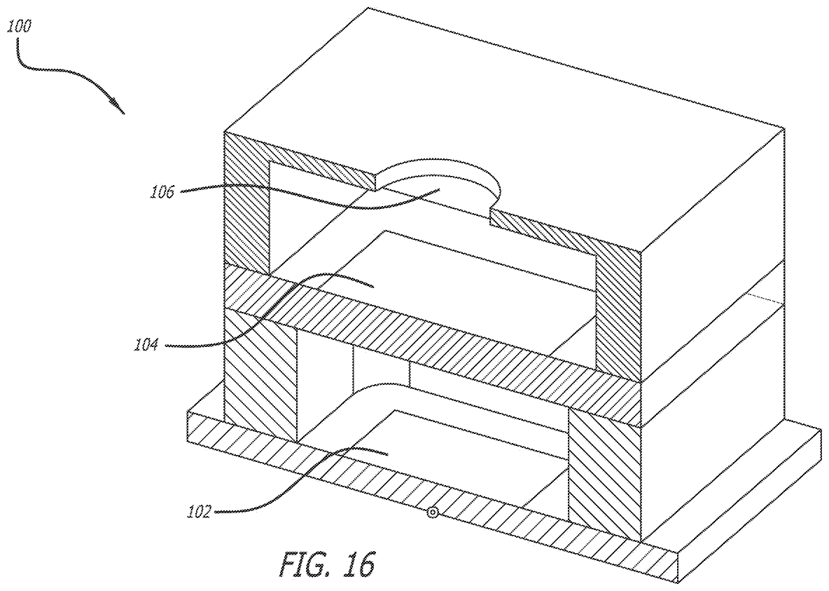

FIG. 16 provides an illustration of an exemplary embodiment of a clear aperture metasurface, where the imaging system (100) is comprised of a rectangular image sensor (102) offset from a single rectangular metasurface (104), and a circular entrance aperture (106) offset from the rectangular metasurface lens (104). In embodiments implementing hybrid metasurface refractive systems, the optical systems are comprised of an entrance aperture, at least one refractive lens and a metasurface lens which is the last optical lens element in the system before the image sensor. In these embodiments of such hybrid systems the entrance aperture and the at least one refractive lens can still have a circular or radially symmetric cross section. Thus, embodiments of such hybrid systems would be comprised of a circular aperture (106) offset from at least one circular refractive lens (not shown) which is then offset from the rectangular metasurface lens (104), as shown in FIG. 16. Again, in such embodiments the metasurface lens has rectangular dimensions which are configured to match a specific image sensor. Although example here describe implementations where the metasurface lens element alone has a rectangular cross section, this need not be a limiting case. For example, the entrance aperture (and stop of the optical system) could also be rectangular or the at least one refractive lens could also be rectangular as long as at least the metasurface lens element, which is the last lens element before the image sensor, has a rectangular cross section.

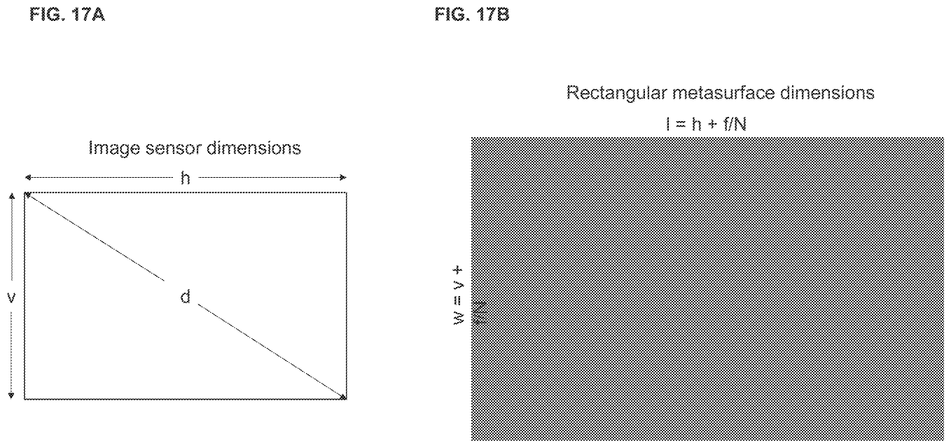

In certain cases, the dimensions of the rectangular lens in the system can be fully characterized by the dimensions of the image sensor in the system and the specifications of the lens. Specifically, as shown in FIG. 17A, an image sensor is characterized by its vertical and horizontal dimensions, v and h, respectively. A lens system is characterized most generally by the f-number of the lens, N, defined as N=f/D where f is the focal length of the optical system and D is the diameter of the lens. Accordingly, as shown in FIG. 17B, the desired rectangular metalense lens width can be shown to be w=v+f/N and the length can be shown to be l=h+f/N. Such definitions of the lens dimensions will result in an image that almost perfectly fills the sensor geometry. In practice, it is desirable to have the image formed by the imaging system be slightly larger than the image sensor dimensions. This oversizing of the image allows for greater tolerance in the final assembly of the lens system. A typical oversizing range may be to take the nominal rectangular lens dimension, as given above, and increase each dimension by 40 microns.

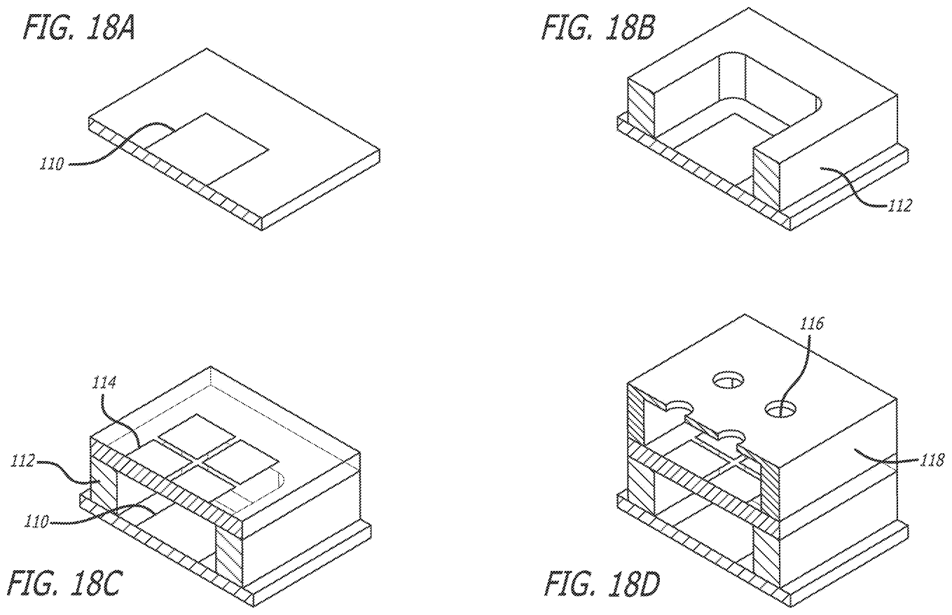

While the above example specifies a single circle aperture coupled with a rectangular lens, in other embodiments an optical system of a N number of apertures over N number of rectangular lenses over a single image sensor may also be provided. For example, the circular apertures and rectangular metasurface lenses may be arrayed in an 2×2 grid over a single image sensor. An example of such a system is shown in FIGS. 18A to 18B. FIG. 18A shows a single image sensor die (110) around which a single spacer (112) can be placed as shown in FIG. 18B. The spacer sets the distance between the rectangular metasurfaces (114), shown in FIG. 18C and the image sensor (110). The last element in the assembly contains a set of circular apertures (116) disposed in association with an additional spacing layer (118) to set the distance between the rectangular metasurface and the circular aperture. A cut away of the full assembly is shown in FIG. 18D.

Although FIG. 18A to FIG. 18D exemplify a 2×2 array of circular apertures over a rectangular metasurface, in general, the grid of circular apertures and rectangular metasurface lenses may be arrayed in any fashion, either symmetric or asymmetric, e.g., 3×3 or 5×2. Additionally, each individual rectangular metasurface and circular aperture comprising the system may have unique dimensions relative to the other aperture metasurface pairs in the system. For example, each aperture diameter in the array can generally be unique or each rectangular lens may be unique. However, the distance between the metasurface lens and the image sensor and the metasurface lens and the circular apertures is generally fixed for the entire system. Changing the mechanical parameters, e.g., aperture size, for each individual component of the array allows the optical properties of each camera in the array to be unique. For example, according to embodiments each sub camera can have a unique f/#, field-of-view, resolution, etc.

### DOCTRINE OF EQUIVALENTS

Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

What is claimed is:

1. An imaging system comprising:
at least one image sensor;
a substrate layer having a substrate thickness, the substrate layer configured to be transparent to a target wavelength of light, the substrate layer having a first surface distal the at least one image sensor and a second surface proximal with the at least one image sensor;
an aperture disposed above the substrate and having an aperture opening disposed therein; and
a single layer of a plurality of identical or unique nanostructured elements comprising a metasurface disposed on one of either the first or second surfaces, such that light impinging on the aperture opening passes through at least a portion of the metasurface such that a specified angular deflection is imposed thereby;
wherein the distance between the aperture and the metasurface are separated by a first distance; and
wherein the aperture and the metasurface are configured to gather light of a specified operational bandwidth across a specified field of view and shift the incoming light such that it focuses on the at least one image sensor at a zero or near-zero degree chief ray angle.

2. The imaging system of claim 1, further comprising an airgap between the second surface of the substrate and the image sensor.

3. The imaging system of claim 2, wherein a spacer layer is disposed within the airgap.

4. The imaging system of claim 2, wherein the metasurface is disposed on the first surface.

5. The imaging system of claim 4, further comprising a narrow bandwidth optical filter disposed on the second surface between the metasurface and the at least one image sensor.

6. The imaging system of claim 4, wherein at least a portion of the aperture is interconnected with the first surface.

7. The imaging system of claim 2, wherein the metasurface is disposed on the second surface.

8. The imaging system of claim 1, wherein the image sensor is in contact with the second surface.

9. The imaging system of claim 1, wherein the field of view is at least ±30 degrees.

10. The imaging system of claim 1, wherein at least the imaging sensor and metasurface have rectangular geometries.

11. The imaging system of claim 1, wherein the at least one image sensor is a complementary metal oxide semiconductor (CMOS) image sensor.

12. The imaging system of claim 1, wherein the target wavelength of light is infrared or visible.

13. The imaging system of claim 1, further comprising a near infrared bandpass filter.

14. An imaging system comprising:
at least one image sensor,
a substrate layer having a substrate thickness, the substrate layer configured to be transparent to a target wavelength of light, the substrate layer having a first surface distal the at least one image sensor and a second surface proximal with the at least one image sensor;
at least one refractive lens disposed above the substrate and configured to focus impinging light on the first or second surface of the substrate layer; and
a single layer of a plurality of identical or unique nanostructured elements comprising a metasurface disposed on one of either the first or second surfaces, such that light impinging on the at least one refractive lens passes through at least a portion of the metasurface elements such that an angular deflection is imposed thereby;
wherein the distance between the at least one refractive lens and the metasurface are separated by a first distance; and
wherein the refractive lens and the metasurface are configured to gather light of a specified operational bandwidth across a specified field of view and shift the incoming light such that it focuses on the at least one image sensor at a zero or near-zero degree chief ray angle.

15. The imaging system of claim 14, further comprising an airgap between the second surface of the substrate and the image sensor.

16. The imaging system of claim 15, wherein a spacer layer is disposed within the airgap.

17. The imaging system of claim 15, wherein the metasurface is disposed on the first surface.

18. The imaging system of claim 17, further comprising a narrow bandwidth optical filter disposed on the second surface between the metasurface elements and the at least one image sensor.

19. The imaging system of claim 14, wherein at least a portion of at least one of the refractive lenses is interconnected with the first surface.

20. The imaging system of claim 15, wherein the metasurface is disposed on the second surface.

21. The imaging system of claim 17, wherein the image sensor is in contact with the second surface.

22. The imaging system of claim 14, wherein the field of view is at least ±30 degrees.

23. The imaging system of claim 14, wherein the at least one refractive lens is selected from the group consisting of plano-convex, convex-plano, bi-convex, bi-concave, planoconcave, or concave-plano.

24. The imaging system of claim 14, comprising at least two refractive lenses comprising a convex-concave lens and concave-convex lens.

25. The imaging system of claim 14, comprising at least two refractive lenses comprising a convex-concave lens, a bi-convex lens and a concave-plano lens.

26. The imaging system of claim 14, wherein at least the imaging sensor and metasurface have rectangular geometries.

27. The imaging system of claim 26, wherein the at least one refractive lense proximal to the metasurface has a circular geometry.

28. The imaging system of claim 23, wherein the image sensor is characterized by a vertical, v, and a horizontal, h, dimension, and wherein the at least one refractive lens is characterized by the f-number of the lens, N, defined as N=f/D where f is the focal length of the optical system and D is the diameter of the lens, and wherein a metalense lens width is given by:
$$w = v + f / N ,$$
and
wherein a metalense length l given by: l=h+f/N.

29. The imaging system of claim 14, wherein the at least one image sensor is a complementary metal oxide semiconductor (CMOS) image sensor.

30. The imaging system of claim 14, wherein the target wavelength of light is infrared or visible.

31. The imaging system of claim 14, further comprising a near infrared bandpass filter.

32. The imaging system of claim 14, wherein the at least one refractive lens is one of: plano-convex, convex-plano, biconvex, biconcave, plano-concave or concave-plano.
